(19) United States
(12) Patent Application Publication
(10) Pub. No.: US 2012/0223423 A1
(43) Pub. Date: Sep. 6, 2012

(54) Lead Frame Strip with Rails Having Bow Reducing Ribs

(75) Inventors: Randy Hsu, Taipei (TW); Chuen-Shing Liao, Taipei (TW)

(73) Assignee: TEXAS INSTRUMENTS INCORPORATED, Dallas, TX (US)

(21) Appl. No.: 13/038,983

(22) Filed: Mar. 2, 2011

(51) Int. Cl. H01L 23/495; H01R 43/00

(52) U.S. Cl. 257/676; 29/825; 257/E23.031

(57) ABSTRACT

A lead frame strip includes an array of sites connected to two side rails which traverse the lead frame strip on two opposite sides. Each site includes a die pad for affixing a semiconductor die and leads for enabling electrical communication between the semiconductor die and a workpiece. Each site is further connected to the two side rails by a sub-rail, which extends between the two side rails. The sub-rail includes a flat portion and a raised or indented rib protruding from the flat portion. The rib has a long dimension parallel to the sub-rail.

### FIELD

Disclosed embodiments relate to packaging of semiconductor integrated circuits (ICs), and more specifically lead frame strips having stiffening structures to reduce bow or sag.

### BACKGROUND

Lead frames are used in the packaging of IC devices. Lead frames are conventionally provided as lead frame strips that comprise a plurality of lead frames mechanically connected by a frame that includes rails. Each lead frame includes a plurality of leads and a center die pad area for mounting an IC die. With high lead count lead frames, a tape may be applied across the leads to prevent bending or displacement of the leads. The die pad area is usually downset from the plane defined by the leads so that when an IC die is placed on the die pad area, it is substantially coplanar with the leads of the lead frame.

Some lead frame strips include buffering structures for addressing thermal stress experienced during package assembly, such as by providing slot-type thermal buffers beyond the location of the leads in the rail region between the lead frames. Conventional slot-type thermal buffers include slots (sometimes referred to as slits) that work with buffer portions of the lead frame. The openings provided by the slits or slots enable the buffer portions to deform under thermal stress. After die attach of the IC die to the die pads, when epoxy resin or similar material thermally hardens during molding to make the resin body for the package, the molded material contracts.

Since the metal lead frame has a lower coefficient of thermal expansion than that of the molded material and is generally very thin, the lead frame is likely to undergo warp or deformation as the resin body contracts. However, because of the presence of the slits or slots, the buffer portions can be deformed to allow the resin body to contract in the longitudinal and transverse directions without causing the lead frame to generally undergo significant warp or deformation as a whole.

### SUMMARY

Disclosed embodiments recognize that lead frame strips while stacked in magazines associated with loading or unloading devices for die bonders can result in damage to the bond wires due to adjacent lead frame strips contacting one another, particularly for large area lead frame strips (e.g., wide lead frame strips). Gravity provides the force for sagging or bowing of the lead frame strips. For example, during transport of lead frame strips in a magazine, it has been found that lead frame strips may sag or bow sufficiently to touch the neighboring lead frame strips above or below in the magazine, which can cause damage the bond wires.

Moreover, the presence of conventional slot-type thermal buffers on the lead frame strip can weaken the lead frame strip and lead to enhanced bowing or sagging that can result in worsening of bond wire damage while in the magazines. Thus, although such slot-type thermal buffers may be helpful for controlling warp or deformation of the lead frame that can damage the IC die, slot-type thermal buffers can reduce the strength of the lead frame strips while in the magazine causing bond wire damage or increasing the level and incidence of bond wire damage during assembly operations.

Disclosed embodiments include lead frame strips that include ribs in sub-rail portions of the lead frame strip for preventing sagging and bowing of the lead frame strip. The ribs can mechanically stiffen the lead frame strip sufficiently to reduce or prevent sagging and bowing of the lead frame strip while in a magazine. Since the sub-rails as well as the side rails are removed by cutting after molding, disclosed ribs are sacrificial (i.e., scrap), and are thus not present on the final packaged IC devices.

Disclosed lead frame strips comprise an array of sites connected to two side rails which traverse the lead frame strip on two opposite sides, where each of the sites include a die pad for affixing a semiconductor die and leads for enabling electrical communication between the semiconductor die and a workpiece (e.g., printed circuit board). Each of the sites is further connected to the two side rails by a sub-rail which extends between the two side rails. The sub-rail has a flat portion and a raised or indented rib protruding from the flat portion, wherein the rib has a long dimension parallel to the sub-rail. In one embodiment the long dimension of the rib covers at least a majority of a length of the sub-rail, and in one embodiment extends from end-to-end along the full length of the sub-rail.

In one embodiment the rib has a raised ridge shape. For downset lead frame applications, disclosed ribs in the sub-rails can be formed concurrently at the lead frame downset process, including optionally also on the die pads as well.

### BRIEF DESCRIPTION OF THE DRAWINGS

FIG. 1A shows a plan view of an example lead frame strip that includes ribs in sub-rail portions of the lead frame for preventing sagging and bowing of the lead frame strip, while FIG. 1B provides a depiction of an example sub-rail showing a flat portion and a raised rib protruding from the flat portion, according to an example embodiment.

FIG. 1C shows a depiction of a example sub-rail showing a flat portion and two (2) parallel raised ribs protruding from the flat portion, while FIG. 1D shows a depiction of a example sub-rail showing a flat portion and two (2) side-by side raised ribs protruding from the flat portion, according to example embodiments.

FIG. 2A shows a cross sectional depiction of a sub-rail including a conventional slot-type thermal buffer, while FIGS. 2B-G show cross section depictions of example sub-rails having various exemplary rib arrangements according to an example embodiments.

FIGS. 3A and 3B show die area vs. warpage results from thermal modeling of a molding process performed at 175° C. for a lead frame strip having conventional slot-type thermal buffers and a disclosed lead frame strip including ribs on sub-rails that provides both stiffening and thermal buffering, respectively.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

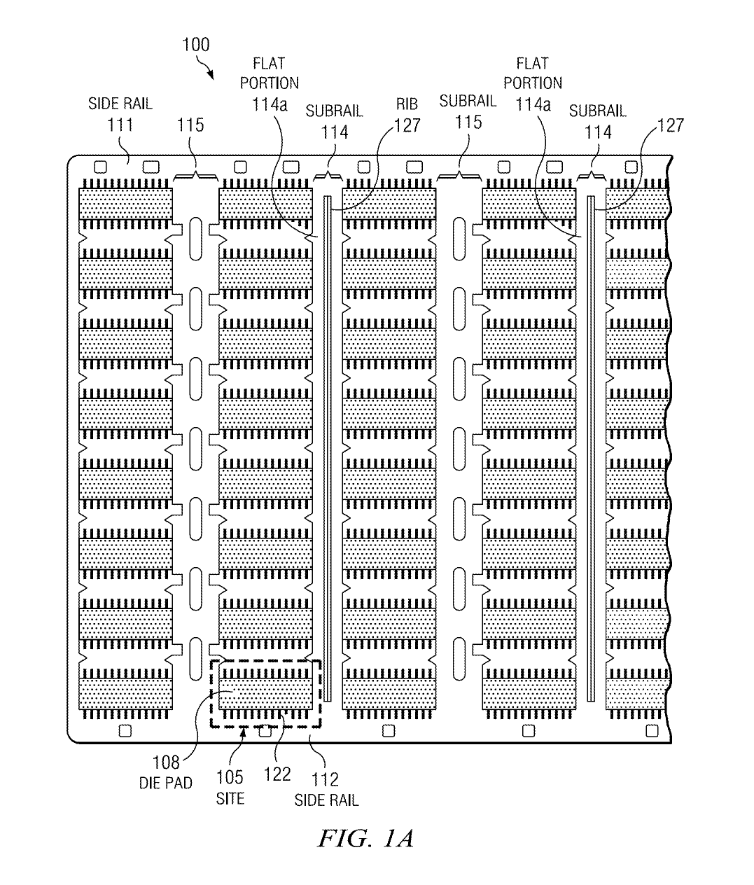

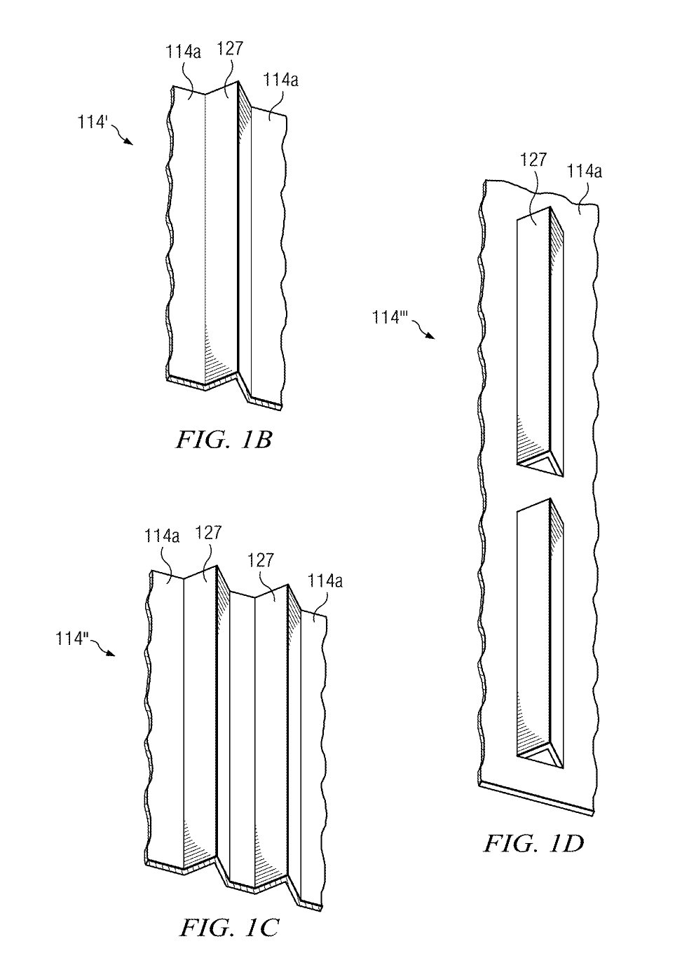

FIG. 1A shows a plan view of an example lead frame strip 100 that includes ribs in sub-rail portions of the lead frame strip for preventing sagging and bowing of the lead frame strip, while FIG. 1B provides a depiction of a example sub-rail 114′ showing a flat portion and a raised rib protruding from the flat portion, according to an example embodiment. Rib 127 can be seen to have a long dimension parallel to the sub-rail 114′ in FIG. 1B, where its long dimension covers at least a majority of a length of the sub-rail 114′.

Lead frame strip 100 comprises an array of sites 105 connected to two side rails 111 and 112 which traverse the lead frame strip on two opposite sides, where the side rails 111 and 112 can be considered to run along the longitudinal axis of lead frame strip 100. Each site 105 includes a die pad or mounting paddle 108 for affixing a semiconductor die (not shown) and leads 122 for enabling electrical communication between the semiconductor die and a workpiece (not shown), such as a printed circuit board (PCB) or an IC die or wafer.

Each site 105 is further connected to the two side rails 111 and 112 by sub-rails 114 which comprise ribs 127 shown alternating with sub-rails 115 that are shown not including ribs 127, which each extend between and perpendicular to the two side rails 111, 112, between columns of sites 105, and can be considered to run in the lateral direction. Although lead frame strip 100 is shown having sub-rails 114 including ribs 127 on every other sub-rail, lead frame strips 100 can have as few as one sub-rail 114 including ribs 127, or as many as every sub-rail 114 including ribs 127. As shown in FIG. 1A, sub-rail 115 is designed for mold lock. The mold runner shown can prevent the mold being broken during mold chase release and avoid scrap material remaining on the mold chase.

Although disclosed ribs 127 are generally described herein being formed in sub-rails 114 for stiffening the lead frame strip, disclosed ribs may also be included in the die pad 108. In this embodiment the die pad 108 also includes at least one raised or indented rib protruding from a flat portion of the die pad.

Disclosed ribs 127 such as shown in FIG. 1B can be formed by a downset or other stamping process and are thus integrally connected to edges of the flat portion 114(a) of sub-rail 114′. The rib 127 shown in FIG. 1B extends continuously and substantially completely across the full length of the sub-rail. As used herein, “substantially completely” refers to extending at least 90% of the length of the sub-rail. FIG. 1C shows a depiction of an example sub-rail 114″ showing a flat portion and two (2) parallel raised ribs 127 protruding from the flat portion 114(a), while FIG. 1D shows a depiction of a example sub-rail 114′″ showing a flat portion 114(a) and two (2) side-by side raised ribs 127 protruding from the flat portion according to example embodiments.

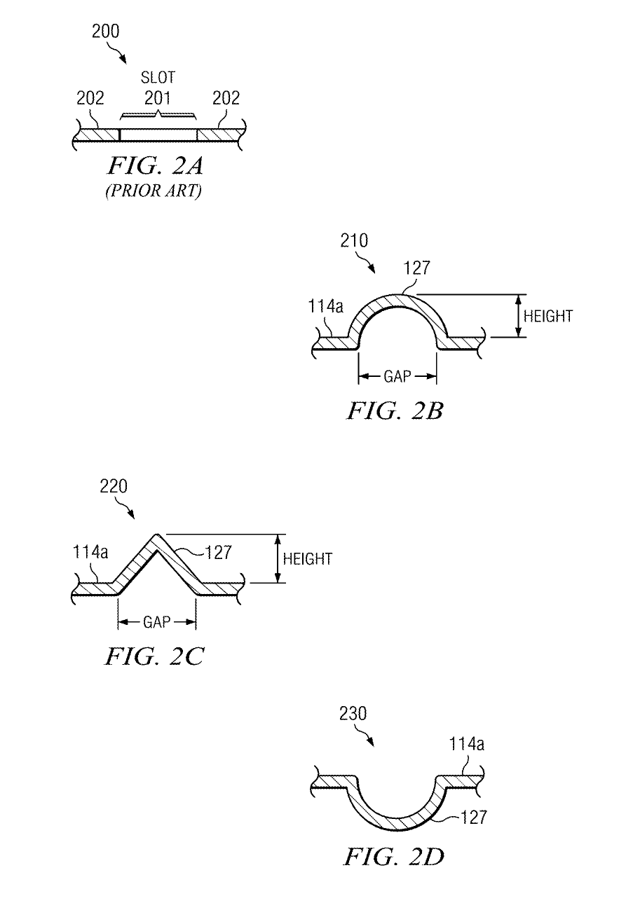

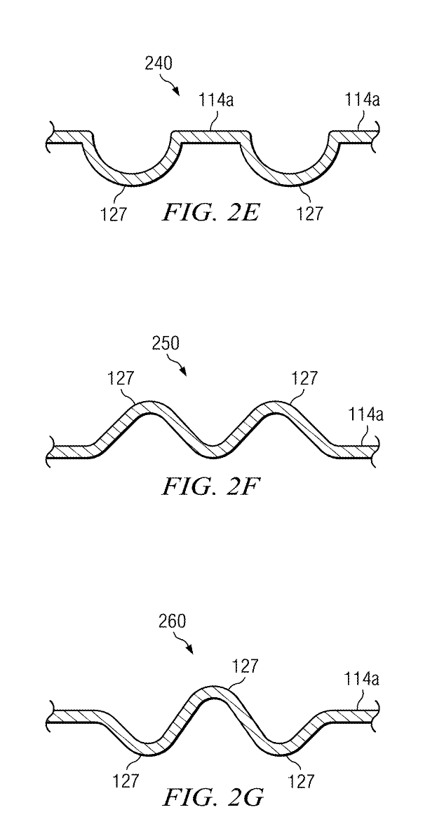

FIG. 2A shows a cross sectional depiction of a sub-rail 200 including a conventional slot-type thermal buffer, while FIGS. 2B-G show cross section depictions of example sub-rails having various exemplary rib arrangements according to an example embodiments. Sub-rail 200 shown in FIG. 2A includes buffer portions 202 that are separated by slot 201. As described above, slot 201 can weaken the lead frame strip enough to allow adjacent lead frame strips to contact while in a loading or unloading magazine which can damage the leads.

FIG. 2B shows a cross section depiction of example sub-rail 210 having a rib 127 embodied as an arc-shaped ridge for stiffening the lead frame strip. Rib 127 of sub-rail 210 defines the gap shown and has a height above the flat portion 114(a). The gap defined by disclosed ribs such as rib 127 shown in FIG. 2B can be from 0.45 mm to 0.75 mm wide in one embodiment. Rib 127 shown in FIG. 2B also defines a height measured from flat portion 114(a). Disclosed ribs 127 can be raised above or protrude below the flat portions 114(a) a maximum height of between 100 and 200 μm in one embodiment.

FIG. 2C shows a cross section depiction of example sub-rail 220 having a rib 127 embodied as a triangular shaped ridge for stiffening the lead frame strip. FIG. 2D shows a cross section depiction of example sub-rail 230 having a rib 127 embodied as an indentation for stiffening the lead frame strip.

FIGS. 2E-G show a cross section depiction of example sub-rails having multiple ribs 127 for stiffening the lead frame strip. FIG. 2E shows an example sub-rail 240 having ribs 127 comprising a pair of parallel indentations 127 for stiffening the lead frame strip. FIG. 2F shows an example sub-rail 250 having ribs 127 comprising a pair of ridges 127 for stiffening the lead frame strip. FIG. 2G shows an example sub-rail 260 having ribs 127 in a corrugated arrangement for stiffening the lead frame strip.

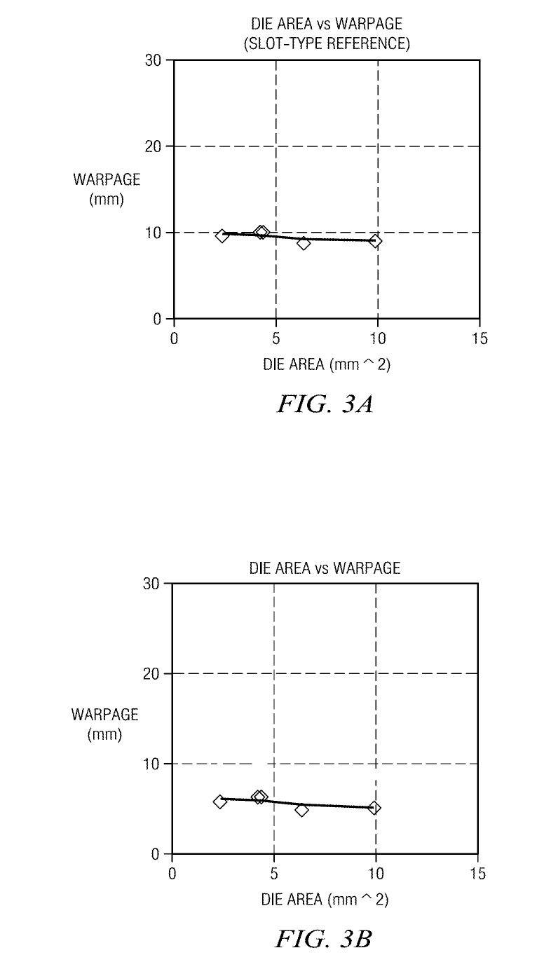

FIGS. 3A and 3B show die area vs. warpage results from thermal modeling of a molding process at 175° C. for a conventional thermally buffered lead frame strip analogous to lead frame strip 100 shown in FIG. 1A except having conventional slot-type thermal buffers analogous to sub-rail 200 shown in FIG. 2A, and a disclosed lead frame strip analogous to lead frame strip 100 including ribs on sub-rails based on sub-rail 114′ shown in FIG. 1B that provide both stiffening and thermal buffering. ANSYS software (ANSYS, Inc. Canonsburg, Pa.) was used to simulate the conditions and situations during a molding process. Warpage can be seen to be reduced by using a disclosed lead frame strip as compared to a conventional thermally buffered lead frame strip by approximately 50% from 9 to 10 mm in warpage to 4-6 mm in warpage. This significant reduction in warpage provided by disclosed lead frame strips as compared to conventional lead frame strips is expected to eliminate or at least substantially reduce bond wire damage during assembly operations while the lead frame strips are stacked in magazines.

Methods of forming disclosed lead frame strips that include ribs in sub-rail portions of the lead frame strip for preventing sagging and bowing of the lead frame strip are also disclosed. In one embodiment forming of the ribs comprises a lead frame downset process that concurrently downsets the die pads. Alternative methods include a separate stamping process.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A lead frame strip, comprising:
an array of sites connected to two side rails which traverse said lead frame strip on two opposite sides;
wherein each of said sites includes a die pad for affixing a semiconductor die and leads for enabling electrical communication between said semiconductor die and a workpiece;
wherein each of said sites is further connected to said two side rails by a sub-rail, which extends between said two side rails,
said sub-rail having a flat portion and a raised or indented rib protruding from said flat portion, and
wherein said rib has a long dimension parallel to said sub-rail.

2. The lead frame strip of claim 1, wherein said long dimension covers at least a majority of a length of said sub-rail.

3. The lead frame strip of claim 2, wherein said rib extends continuously and substantially completely across said length of said sub-rail.

4. The lead frame strip of claim 1, wherein said rib is integrally connected to edges of said flat portion.

5. The lead frame strip of claim 1, wherein said die pads include a raised or indented rib protruding from a flat portion thereof.

6. The lead frame strip of claim 1, wherein said die pads are downset relative to said plurality of leads.

7. The lead frame strip of claim 1, wherein said rib has a ridge shape.

8. The lead frame strip of claim 1, wherein a gap created by said rib has a width between 0.45 mm to 0.75 mm.

9. The lead frame strip of claim 8, wherein said rib is raised above or protrudes below said flat portion a maximum height of between 100 and 200 μm.

10. A method of forming lead frame strips, comprising:
providing a lead frame strip comprising an array of sites connected to two side rails which traverse said lead frame strip on two opposite sides, wherein each of said sites includes a die pad for affixing a semiconductor die and leads for enabling electrical communication between said semiconductor die and a workpiece; each of said sites being further connected to said two side rails by a sub-rail, which extends between said two side rails, and
forming at least one raised or indented rib in said sub-rails so that said sub-rails have a flat portion and said rib protruding from said flat portion, wherein said rib has a long dimension parallel to said sub-rail.

11. The method of claim 10, wherein said forming said rib comprises a lead frame downset process that concurrently downsets said die pads.

12. The method of claim 10, wherein said long dimension covers at least a majority of a length of said sub-rail.

13. The method of claim 12, wherein said rib extends continuously and substantially completely across said length of said sub-rail.

14. The method of claim 10, wherein said rib is integrally connected to edges of said flat portion.

15. The method of claim 10, wherein said rib has a ridge shape.

16. The method of claim 10, wherein said die pads are downset relative to said plurality of leads.

17. The method of claim 10, wherein a gap created by said rib has a width between 0.45 mm to 0.75 mm.

18. The method of claim 10, wherein said rib is raised above or protrudes below said flat portions a maximum height of between 100 and 200 μm.

19. The method of claim 18, wherein said forming further comprises forming at least one raised or indented rib protruding from a flat portion of said die pad.
